(19) United States
(12) Patent Application Publication
(10) Pub. No.: US 2026/0193078 A1
(43) Pub. Date: Jul. 9, 2026

(54) MEMS ROTATING MICRO ACTUATORS

(71) Applicant: Preciseley Microtechnology Corporation, Burnaby (CA)

(72) Inventors: Tiansheng Zhou, Burnaby (CA); Lawrence Lam, Burnaby (CA)

(21) Appl. No.: 19/559,326

(22) Filed: Mar. 6, 2026

Related U.S. Application Data
(63) Continuation of application No. PCT/CA2024/000016, filed on Sep. 9, 2024.
(60) Provisional application No. 63/581,449, filed on Sep. 8, 2023.

(51) Int. Cl. B81B 3/00; G02B 26/02

(52) U.S. Cl. CPC B81B 3/0054; G02B 26/023; B81B 2201/032; B81B 2201/034; B81B 2201/045; B81B 2201/047; B81B 2203/0172; B81B 2203/0307; B81B 2203/051; B81B 2203/056

(57) ABSTRACT

A MEMS structure that can amplify displacement of attached blocker in a small form factor is disclosed. The displacement amplification structure comprises two deformable beams that are anchored to either side of a pivoting body with a defined distance. The other ends of the beams are attached to actuators that can generate small translation movement in the opposing direction over a radius and produce torque on the pivoting body and causing it to rotate.

### CROSS-REFERENCE TO RELATED APPLICATIONS

This application is a continuation of International Application No. PCT/CA2024/000016, filed Sep. 9, 2024, published as WO 2025/050201, which claims the benefit of U.S. Provisional Application No. 63/581,449, filed Sep. 8, 2023, the entire contents of each of which are incorporated herein by reference.

### TECHNICAL FIELD

The present disclosure is directed towards the rotational type of electrothermal actuator used for MEMS (Micro-Electro-Mechanical Systems) optical shutter/chopper, variable attenuator (VOA), optical switch, tunable filter application.

### BACKGROUND

The MEMS (Micro-Electro-Mechanical Systems) shutters have wide applications in fiber optic communication, test instrument, laser system, where optical attenuator, optical shutter, or optical chopper are integral parts of the products. A MEMS device that can generate large displacement to momentary or permanently block pin hole or optical slits is highly desirable for optical system to enable active noise cancellation and self-calibration, in terms of high-power laser system, the MEMS shutter can also be used to ensure eye-safety.

### SUMMARY

According to an aspect, a MEMS structure that can amplify displacement of attached blocker in a small form factor is disclosed. The displacement amplification structure comprises two deformable beams that are anchored to either side of a pivoting body with a defined distance. The other ends of the beams are attached to actuators that can generate small translation movement in the opposing direction over a radius and produce torque on the pivoting body and causing it to rotate.

In some embodiments, a pivoting body can be in the form of circular, rectangular or any shape that have a width that is smaller than the displacement of the attaching blocker but strong to withstand a shear force applied to the body.

In some embodiments, one, or multiple deformable beams are shaped in a way to be flexible and deformable in the direction that pivoting body is rotating. The deformable beam is curved around the pivoting body to ensure the applied force is tangential to the pivoted circle to ensure constant rotating motion instead of lateral shifting as the actuators provides work to the mechanical system.

In some embodiments, a blocker extended out by a beam is attached to the rotating ring and can be used to block, attenuate, or reflect the light travelling through the MEMS devices.

In some embodiments, the displacement of blocker is amplified and reaches over 1000 μm as the pivoting body rotated in either direction (clockwise or counterclockwise) by the actuators which displaces by about 50 μm to 100 μm. The actuation motion can be controlled precisely via the control of input voltage, current, or magnetic strength and cause the block to be partially or fully open and close for light attenuation, modulation, switching purpose. The actuation motion may be produced by, for example, but not limited, by electrothermal actuation (thermal expansion), or by electrostatic force, or by magnetic force, or by piezo-electric force.

In some embodiments, the pivoting body may be connected by more than one actuating device to generate more torque to increase the rigidity of the actuating system.

In some embodiments, the attached blocker can be of any shape and different for example, but not limited to rectangular, circular, and oval or arbitrary shape with size ranging from a few um to a few millimeter long and wide.

In some embodiments, the attached blocker may have a profiled edge feature to improve diffraction of beam going through the edge of the block.

In some embodiments, an array of embodiments may be produced on the same substrate for display application where an array of beams can be attenuated, switched, modulated.

In some embodiments, the position of the blocker may be locked by moving and movable pin into the opposing pin anchored to the blocker as it is actuated to the designated position. Once the pins are travelled to the designated to position, the actuator can be turned off on the blocks side and subsequently the actuator of locking pin can be turned off to hold the blocker permanently until a reversed sequence is applied to the device.

In some embodiments, the MEMS optical shutter comprises an optical slit that is fabricated within the device. The lithographically defined optical slit and the shutter provide precise control over dimension and vertical separation and making the system integration easier.

In some embodiments, the MEMS optical shutter comprises an optical pin hole that is fabricated within the device. The lithographically defined pin hole and the shutter will have precise control over dimension and vertical separation and making the system integration easier.

In some embodiments, the MEMS rotating micro actuator may carry an optical component such as reflector, optical grating, optical lens, optical prism, fiber, or waveguide, among others, to manipulate light in varies wavelength range.

In some embodiments, the MEMS rotating micro actuator may have a covering plate placed onto the actuator to shield the thermal actuator from ambient air to reduce temperature dependency. Part of the covering plate can be used to create precise working distance and clearance from the moving shutter to the attached system to ease assembly tolerance.

### BRIEF DESCRIPTION OF THE DRAWINGS

These and other features will become more apparent from the following description in which reference is made to the appended drawings, the drawings are for the purpose of illustration only and are not intended to be in any way limiting, wherein:

FIG. 1 is a perspective view of a latching MEMS shutter that generates in plane rotating movement on blocker to interfere the beam that is travelling out of plane from the presented drawing.

FIG. 1a is a top view of a MEMS variable attenuator that uses one or more embodiments according to the present disclosure.

FIG. 1b is a top view of a MEMS shutter that uses one or more embodiments according to the present disclosure with detail on how the device can be latched.

FIG. 1c is a perspective view of a MEMS rotating micro actuator carrying an optical grating for tunable optical filter, spectrometer application.

FIG. 2 is a top view of the rotating actuator driven by a pair of in-plane actuating thermal actuators as they are designed to travel in the opposing direction to generate torque and cause rotating motion on the inner circular pivoting body.

FIG. 2a is top view of the variation of pivoting body.

FIG. 2b is a top view of the variation of MEMS rotating micro actuator with one actuating device.

FIG. 2c is a top view of the variation of MEMS rotating micro actuator with multiple actuating devices connecting to the pivoting body.

FIG. 2d reveals the details on the deformable beam 10 when it is not deformed.

FIG. 2e shows how the deformable beam 10 is deformed under applied force.

FIG. 3 is a top view of one part of the thermal actuator as implemented in one or more embodiments according to the present disclosure.

FIG. 4 is a top view of the rotating actuator driven by a pair of in-plane actuating electrostatic actuators as they are designed to travel in the opposing direction to generate torque and cause rotating motion on the inner circular pivoting body.

FIG. 5 is a top view of one part of in-plane moving electrostatic actuators as implemented in one or more embodiments according to the present disclosure.

FIG. 6 is a top view of variation of the blocker that can be implemented for different optical application.

FIG. 7 is a top view of the MEMS shutter array.

FIG. 8 is a top view of the MEMS shutter with two blockers.

FIG. 9 is illustration of 2×2 optical bypass switch implemented by one or more embodiments according to the present disclosure.

FIG. 10 is the process flow for making one or more embodiments according to the present disclosure.

FIG. 11 is the perspective view of the optical feature that can be integrated to the substrate.

FIG. 12 shows a first embodiment that is used to construct the MEMS shutter device with an integrated optic elements such as an optical slit.

FIG. 13 shows a second embodiment that is used to construct the MEMS shutter device with an integrated optic elements such as an optical slit.

FIG. 14 shows a cross section of the construction of an embodiment of the MEMS shutter.

### DETAILED DESCRIPTION

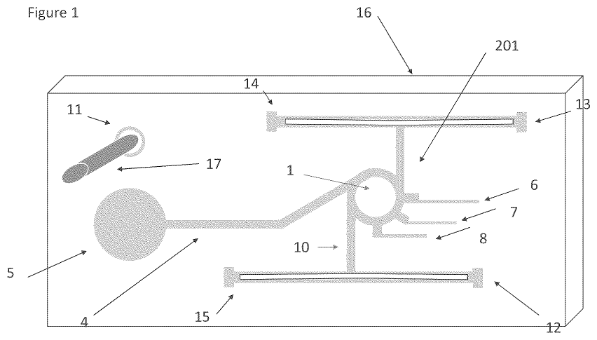

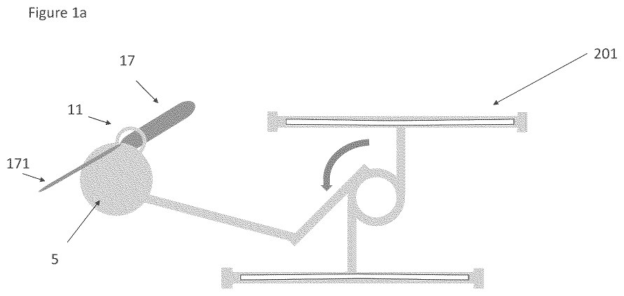

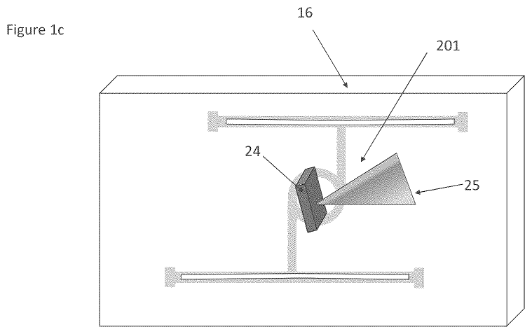

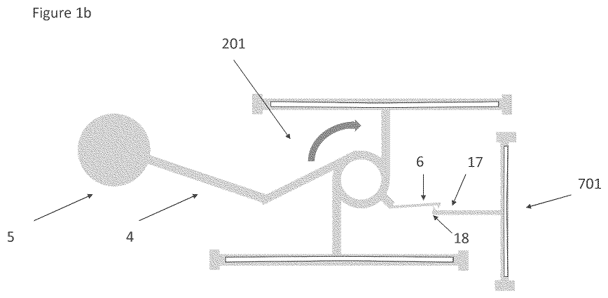

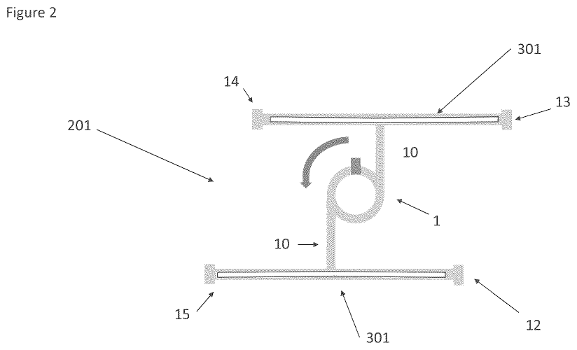

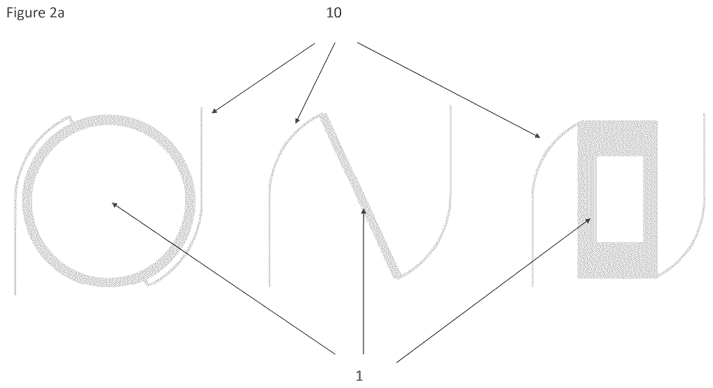

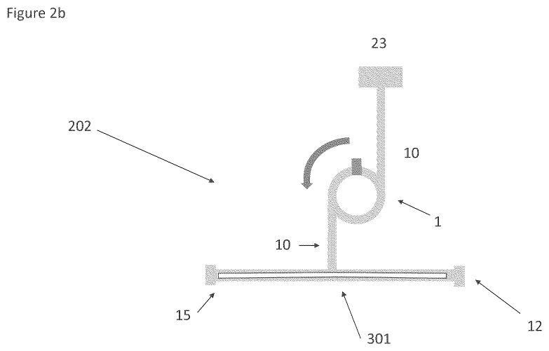

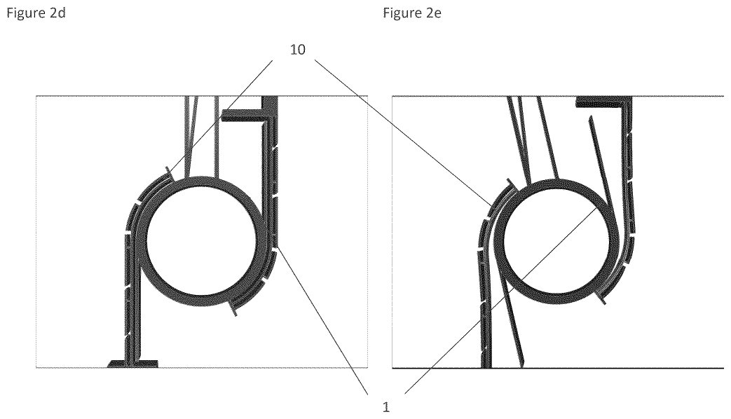

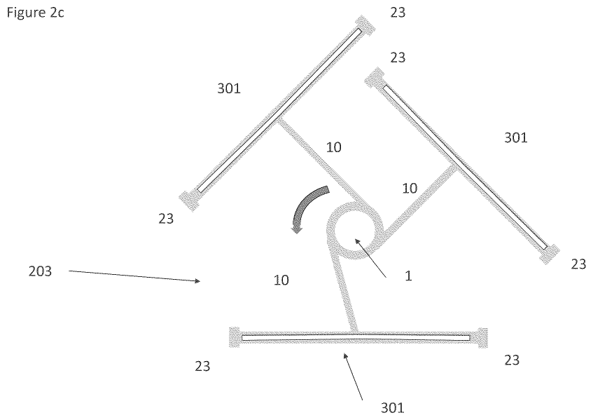

FIG. 1a shows an example of the MEMS shutter driven by the MEMS rotating micro actuator 201. The MEMS shutter includes a substrate 16, the MEMS rotating micro actuator 201, the optical blocker, a pin hole 11 embedded in the substrate, and a locking device 6, 7, 8. The substrate 16 may be comprised of a variety of typical micro-machinable material such as Si, glass, quartz, polymer, or even metal, in this present embodiment is silicon. The MEMS rotating micro actuator 201 which has more detail shown on FIG. 2, includes 4 anchoring points 12, 13, 14, 15 for the two actuators 2 and 3 that are facing the opposite of each other. The actuators pair 2 and 3 each have extending arm 9 and 10 and connects to the circular pivoting body 1 on either side that is 180 deg offset from each other. The actuator pair may be constructed by a variety of actuation mechanisms such as electrothermal expansion beams 301, electrostatic comb drive 501, piezo-electric actuator, or electromagnetic actuator if a translation or in-plane motion can be generated applied to either side of the pivoting body 1 and cause the pivoting body 1 to rotate. An optical blocker 5 is connected to the circular pivoting body 1. As MEMS rotating micro actuator 201 energizes, a torque will be applied to the circular pivoting body 1 and cause a rotational movement and hence initiate the displacement of the blocker 5. The direction of the torque may be clockwise or counterclockwise depending on the direction of motion of two actuators 2 and 3. The actuator pair 2 and 3 move towards the center of pivoting body 1 and rotate the pivoting body clockwise; they can also be designed to move away from the center of the circular pivoting body 1 and cause the pivoting body to rotate counterclockwise. The displacement of blocker 5 is then amplified according to the length of extending arm 4 relative to the radius of pivoting body 1. The blocker 5 may be made in variety of shapes or form such as circular blocker 601 and other variation such as a rectangular blocker 602 for blocking a light off the slits.

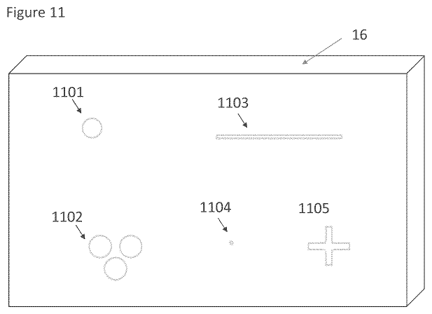

The MEMS shutter may also include a pin hole 11 or other form of variation as shown in FIG. 11 such as a large circular fiber connecting port 1101, a group of light ports 1102, a precise entrance slits 1103, a small pin hole 1104, or a fiducial 1105.

The MEMS shutter may include a locking mechanism at varies position 6, 7, and 8 to maintain the shutter position without power. Upon the activation of the in-plane rotating lever structure 201, the beam 17 that is passing through pin hole 11 will block completely or partially to allow for beam 17 off and on switching function.

FIG. 1a, displayed in top view, shows an example of the MEMS variable optical attenuator moving continuously via controlling the displacement of the in-plane rotating lever structure 201. As the rotating displacement of in-plane rotating lever changes according to the input signal via voltage, current or magnetic force the blocker 5 attenuates via blocking partially the light beam 17 coming out of plane through pin hole 11. As a result, the beam size of beam 17 is reduced and become 171 reaches back to detector or output fiber and results in optical signal attenuation. The MEMS variable optical attenuator may include of circular blocker 601 and other variation such as a rectangular blocker 602 for block a light off the slits, an irregular shape of block 603 for irregular beam shape, a blocker 604 with periodical slits 605 to influence diffraction of the beam going through it or a blocker 607 with edge feature 606 to improve wavelength dependency on the optical attenuator while working with broadband light source.

FIG. 1b shows a latching MEMS shutter that is locked in position by the locking mechanism. The latching MEMS shutters includes a MEMS rotating micro actuator, a blocker with extension arm 4, a locking feature 6 attached to the circular pivoting body 1, and additional in-plane moving actuator 701 with an extension arm 17 with a hook 18. If the shutter is required to be locked in position without power, the MEMS rotating micro actuator 201 will be energized and controlled via the input signal to actuators 2 and 3 that the locking feature 6 is lines up closely with the hook 18. While maintaining the displacement MEMS rotating micro actuator 201, the additional actuator 701 will be energized a displace to allow hook 18 reach in to locking feature 6 and makes contact. The MEMS shutter is then locked in position and all the drive can be powered off to save energy. To release the lock, the reverse action will be executed. First energize the additional locking mechanism 701 and to disengage the hook 18 from locking feature 6, and then energize the MEMS rotating micro actuator 201 to make room for hook 18 and extension arm 17 to retrieve. De-energize the additional locking device 701 and then turn off MEMS rotating micro actuator 201 to reposition the shutter back to the original state.

FIG. 1c shows a perspective view of the MEMS rotating micro actuator 201 carrying a free-standing optical reflective grating. The system includes a MEMS rotating micro actuator 201 anchored to the substrate 16, an optical reflective grating 24. Using a wafer bonding or flip chip bonding process, an optical element such as shown optical reflective grating 24, or lens, mirror, prism may be attached to the MEMS rotating micro actuator 201 to tunable optical system. As the optical reflective grating 24 rotates about the center of the pivoting body, the incident light will diffract and separate different wavelengths of light 25 in space. Depending on the incident angle, the rotation of the grating, different wavelength can be filtered and sent to the output channel or fiber. This function is highly desirable for building a tunable optical filter or a spectrometer. A large angular displacement, larger than 15 mechanical degrees can be easily achieved. Unitizing the large force generated by one or more thermal actuators 301, a discrete part such as an optical grating with large inertia can be driven. A stronger flexure that is released and suspended can also be incorporated to make sure the device can endure assembly processes.

FIG. 2 reveals the construction of MEMS rotating micro actuator 201. The MEMS rotating micro actuator includes pivoting body 1, two deformable beams 10, two actuators 301. The first thermal actuator 301 is anchored to substrate 16 at anchoring point 12, 15. A second identical thermal actuator 301 that is placed in 180 degrees of the first thermal actuator 301 and anchored to substrate 16 at anchoring point 13, 14. Both actuators will be energized at the same time. As the heat generated by the electrical current passing through the thermal beam 2. The thermal beam 2 will be thermally expanded causing joule heating and deforms to general in-plane displacement. The motion of the thermal beam 2 is then translated to the deformable flexure beam 10 and causes the pivoting body 1 to rotate.

FIG. 2a. shows the example variation of pivoting body 1. The pivoting body can be present in many shapes and size, such as a circular ring, straight bar, and rectangular bracket or solid to hold the deformable flexure 10. The pivoting body 1 is designed to rotate since it could be symmetrical, and strong enough to endure the shear force that is applied through deform flexure 10 anchored on either side of the body.

FIG. 2b shows a variation of MEMS rotating micro actuator 202 which includes a pivoting body 1, two deformable beam 10, one actuator 301 and three anchoring points 12, 15, and 23. The first thermal actuator 301 is anchored to substrate 16 at anchoring point 12, 15. The second actuator is replaced with a fixed anchor to provide the reaction force as the pivot body 1 being pushed by the actuator 301 and causes pivoting body 1 to rotate.

FIG. 2c shows a variation of MEMS rotating micro actuator 203 which includes a pivoting body 1, three deformable beam 10, threes actuator 301 and multiple anchoring points 23 to support all the actuators. All the actuators will be energized and push the pivoting body 1 through the deforming beam 10 on the tangential line and cause pivoting body 1 to rotate.

FIG. 2d reveals the details on the deformable beam 10 when it is not deformed and is compared with FIG. 2e which shows how the deformable beam 10 is deformed. FIG. 2e also reveals how the stress is distributed across the deforming beam. The beam is curved around the pivoting body 1 to ensure the applied force is always tangential to the pivoted circle to ensure constant rotating motion instead of lateral shifting as the actuators provides work to the mechanical system.

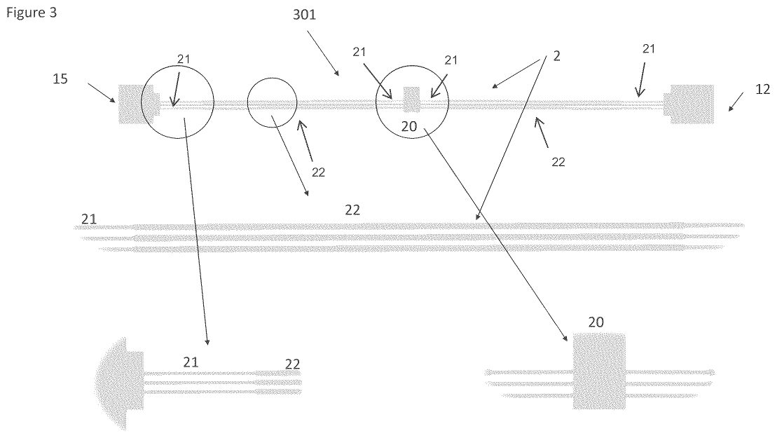

FIG. 3 shows the details on the one embodiment of an electro-thermal actuator 301 that can be used with the MEMS rotating micro actuator. The preferred electro-thermal actuator preferably includes at least two anchoring points 12 and 15, with at least one beam coupled at one end to anchor point 12 and at a second end to anchor point 15. The at least one beam can further include as multiple beams as shown in FIG. 3. While the preferred embodiment has 3 beams, the number of beams can vary depending on the amount of structural support required for a particular application. The beams are preferably made of silicon, but other semi-conductive or conductive material could be used and would be known to a person skilled in the art. The beams may include four connecting sections 21 and two main sections 22. A connecting block 20 is located in the center of the beam. The connection sections 21 are located adjacent either side of the connecting block 20 and adjacent the anchoring points 12 and 15. The at least one beam preferably has a slight curvature between the anchoring points 12 and 15 which preferably peaks at the connecting block 20. The curvature aids in defining the connecting block travelling direction and to allows the connecting block 20 to travel upward as the whole beam thermally expands. As shown in FIG. 3, the connecting sections 21 are thinner, while the main sections 22 are thicker. The connection section 21 has smaller width than main section 22 to ensure optimum flexibility and optimize stress distribution during deformation. It should be noted that other electro-thermal actuators known to a person skilled in the art could be used.

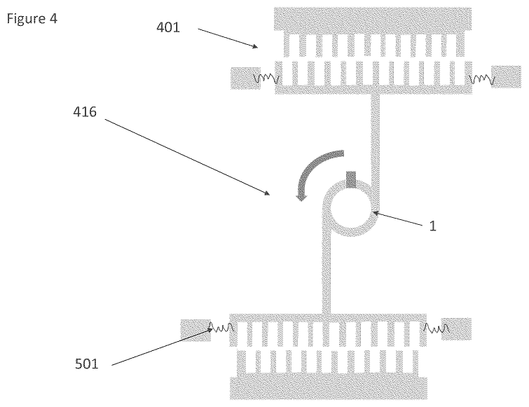

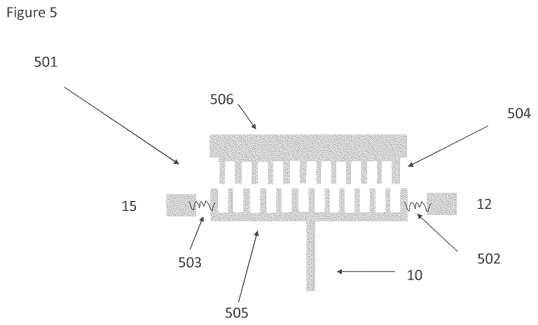

FIG. 4 shows a variation of the MEMS rotating micro actuator structure 201. The MEMS rotating micro actuator 416 includes two electrostatic comb drives 401 and 501 facing 180 deg of each other. FIG. 5 shows the details of one electrostatic comb drive 501 which includes three anchoring points 12, 15, 506. Anchoring points 12 and 15 are attached with spring 503 and 502 that are flexible to deform and attached to movable comb. One electrostatic comb drive 513 that is free to move and suspended from the anchoring point 12 and 15 can be applied with potential difference relative to the potential of stationary comb drive 506. The electrostatic force generated from the comb drive will generate an in-plane motion on extension arm 10. The MEMS rotating micro actuator 416 can then be rotated via the torque applied from extension arm 10 from each of the opposing electrostatic drive 401 and 501. Even though the displacement of in-plane comb drive is typically small due to the small force it can generate, the amplification of displacement of the MEMS rotating micro actuator 416 using an electrostatic drive pair 401 and 501 can be useful to make a smaller shutter block to rotate and block or attenuate light and yet making the MEMS device more power efficient.

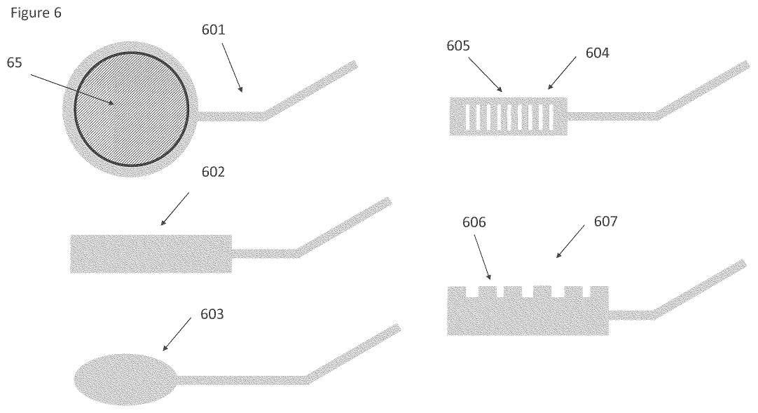

FIG. 6 reveals the variation of the optical blocker that can be attached to the MEMS rotating micro actuator to realize the MEMS shutter, variable attenuator, MEMS optical encoder, MEMS optical switch application. A circular MEMS blocker 601 includes a blocker, preferably made of silicon, which can be transmissive to IR wavelength. Hence a layer of material 65 may be deposited to the blocker to block off or reflect the IR light to stop light from going through the pin hole underneath. The material 65 can be comprised of, but not limited to, metal or alloy metal such as Au, Al, or their alloys. The material may also be comprised of dielectric material or polymer that is opaque to other wavelengths of light as desirable. A rectangular blocker 602 may be used to block off light going through a thin slit. An oval or irregular shape mirror 603 may also be used to block off beam with irregular shape. A blocker 604 with periodic pattern 605 may be produced easily during the microfabrication process to make block a movable grating. A blocker 607 with edge feature 606 can be designed to influence the diffraction as beam going through edge of the blocker and improve wavelength dependency loss when working with a broadband light source.

FIG. 11 reveals the variations of the optical aperture 11 that can easily integrate to one or more embodiments according to the present disclosure. Several examples of optical aperture or feature such as a large circular fiber connecting port 1101, a group of light ports 1102, a precise entrance slits 1103, a small pin hole 1104, or a fiducial 1105 can be transferred to substrate 16 or be transferred to another layer of silicon or material. A circular fiber connecting port 1101 may facilitate the coupling of input and output fiber to the MEMS shutter well as the location of the fiber connecting ports can be precisely placed to the center of optical path and allowing the blocker 5 to block or attenuate beam consistently between each assembled device. A group of light ports 1102 may be integrated to the MEMS shutter for a multi-core fiber to allow the block to control intensity of the light source without adjusting the power supply of the light source and disrupt the black body radiation thermal equilibrium. A precise entrance slits 1103 with high quality edge definition with a width ranging from a few um to hundreds of um and with a few hundred um length can be made on the substrate or on another layer of silicon to refine the spectral resolution of a spectrometer.

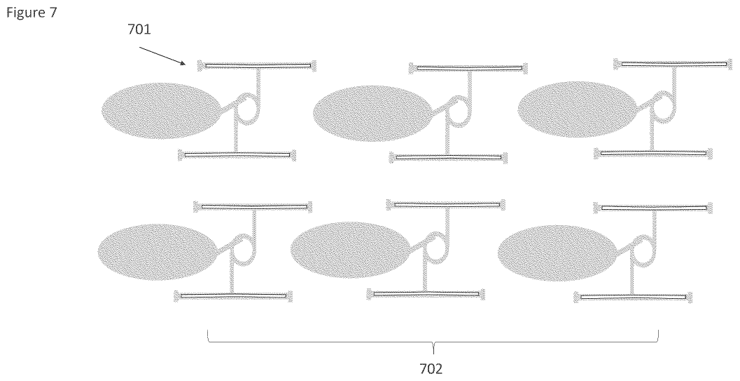

FIG. 7 shows an array of MEMS shutter 701 and forms MEMS shutter array 702 which can be useful for display applications. As shown to reveal a concept, a MEMS shutter array 702 includes 2 rows of MEMS shutter 701 and 3 columns of MEMS shutter 701. The array may be of any suitable size that satisfies the following condition. The number of elements array is dependent on the size of the MEMS shutter 701 and size of the substrate 16, which is by the processing equipment.

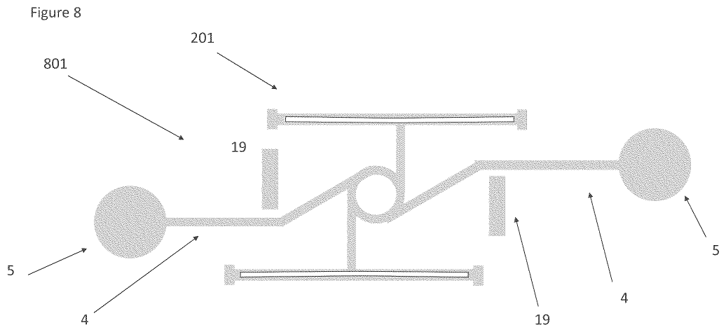

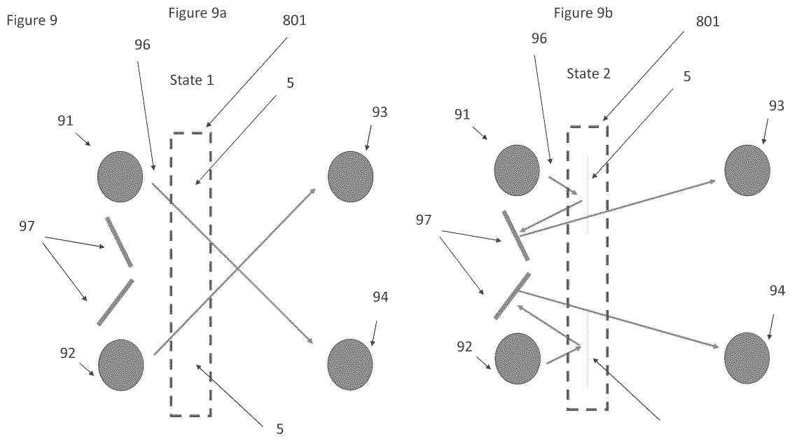

FIG. 8 shows a twin MEMS shutter 801 driven by one MEMS rotating micro actuator 201. A twin MEMS shutter includes one MEMS rotating micro actuator 201, and two blocks 5, and two extension arms 4. Some application for the MEMS shutter may be sensitive to vibration, making a balanced system can reduce settling time, and avoid large oscillation due to inertia. A bumper feature 19 that is anchored to the substart 16 can be placed on both extension arm to limit the displacement of the arms wobbling perpendicularly to the surface of the substrate 16. The twin shutter 801 shown here may also be applicable for 2×2 optical bypass switch application as shown in FIG. 9.

FIG. 9 is a top view of the 2×2 optical bypass switch which includes two optical inputs 91 and 92, two optical outputs 93 and 94, a twin MEMS shutter 801 placed in the optical path of both channels, two fix mirror 97. At working state 1 as shown in FIG. 9a, signal coming from inputs 91 will reach to output 9, and vice versa the signal will reach from input 92 to output 93 whereas the both beam with travel through the twin MEMS shutter 801. At the working state 2 as shown in FIG. 9b, the twin MEMS shutter 801 will be turned on, the blockers 5 will move into the optical path between input 91 and output 94 and redirect the light in two the fix mirror 97 and bounce the light into output 93. Vice versa the second channel where signal is travelling through input 92 will be redirected into output 94. A latching feature 701 will make the 2×2 optical bypass switch practical as switching state usually needs to be maintained for a long period of time.

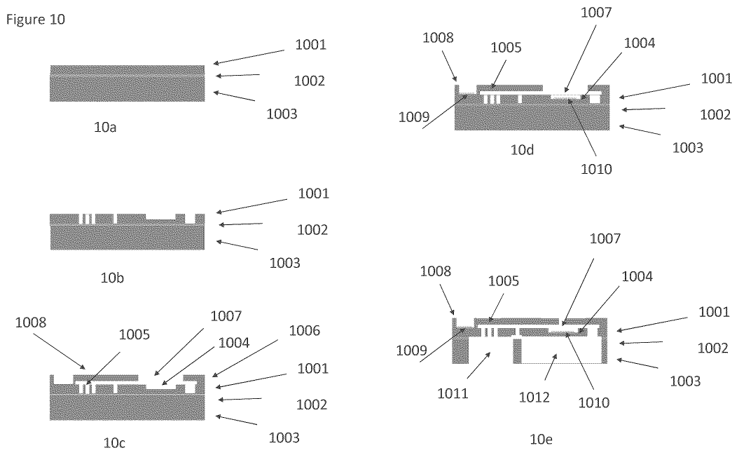

FIG. 10 shows a process flow for fabricating one or more embodiments according to the present disclosure. As shown in 10a, starting with a Silicon-on-insulator (SOI) that includes a device layer with highly doped silicon 1001, buried box layer 1002, and handle layer 1003. As shown 10b, a set of lithography patterning and deep reactive Ion Etching (DRIE) will be used to etch device layer 1001 to define 1005 the MEMS rotating micro actuator 201 and the blocker 5. A second DRIE etching may be used to reduce the thickness 1004 of the blocker 5 to reduce mass for better mechanical performance. As shown in 10c, a second prime wafer 1008 may be used. The prime wafer 1008 is patterned and etched from both sides. First shallow etching is defined to be above the movable feature such as MEMS rotating micro actuator 201 and blocker 5, among others, to avoid interference of movement caused by the top layer 1006 and protect the moving feature in the subsequent processing. The second etch will be etch through prime wafer 1008 to create the desirable opening for optical path or optical feature as well as the opening for bondpad location. The etched prime wafer 1008 is bonded to the first SOI wafer via wafer bonding. As shown in 10d, the metal layer 1009 and 1010 is deposited through the opening that is patterned on prime wafer 1008 via shadow metal process. Finally, as shown in 10e the handle 1003 which was patterned in the previous processing etch will be dry or wet etched to create feature 1011 and 1012 and the buried oxide 1002 will etched via vapor HF and release the structure.

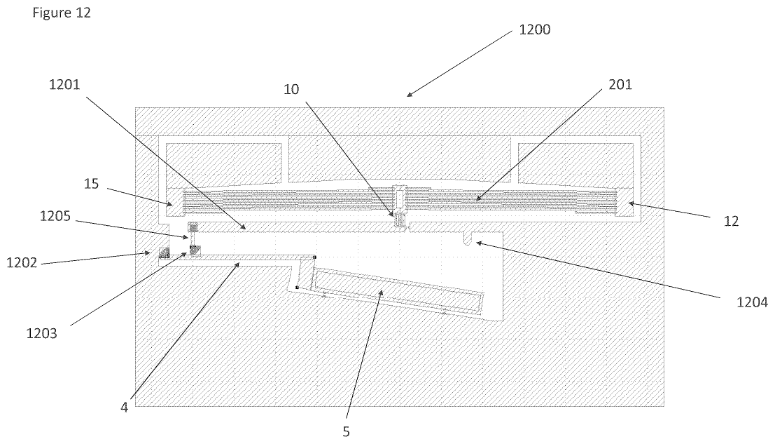

FIG. 12 illustrates an embodiment 1200 that is used to construct the MEMS shutter device with an integrated optic elements such as an optical slit, aperture, or grating, among others. The embodiment 1200 includes thermal actuator 201 that is anchored at two locations 15, 12 and onto the substrate. The thermal actuator 201 may include three mechanical beams 10, 1201, 1205 to translate the in-plane movement onto the blocker arm 4 that has 2 pivoting points 1202, and 1203. Blocker 5 is attached to the end of blocker arm 4 and receives the displace amplification of the leveraging system when the thermal actuator 201 energizes. The embodiment 1200 may also have displacement limiter 1204 to prevent the device from overtravel and over-stress the delicate MEMS structures.

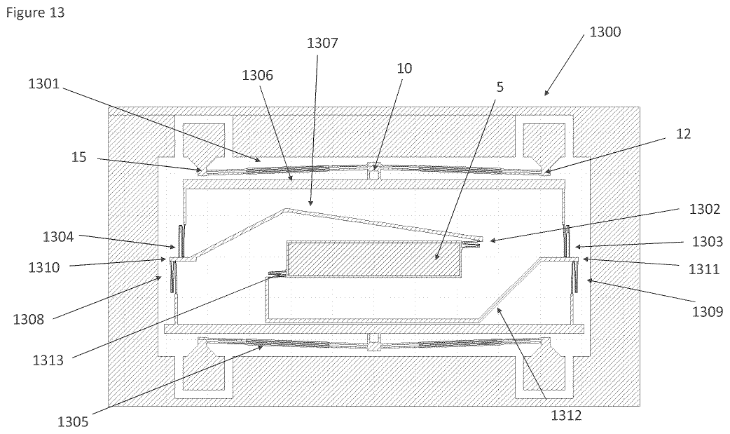

FIG. 13 illustrated an embodiment 1300 that is used to construct the MEMS shutter device with an integrated optic elements such as an optical slit, aperture, or grating, among others. The embodiment 1300 may include at least one thermal actuator 1301 that is anchored at two locations 15, 12 and onto the substrate. The thermal actuator 1301 may include mechanical links 10, 1306 which translate the movement onto the flexures 1304, 1303. While the other thermal actuator 1305 pulls in the opposite direction, mechanical link 1307 rotates and pivots from 1310. Similarly, mechanical link 1312 rotates and pivots from 1311 simultaneously with mechanical link 1307. The displacement of blocker 5 is then amplified by extending the length of mechanical 1307 and 1312. Two flexible flexures 1302, and 1313 connect to the opposing corner of blocker 5 to maintain the balance of the mechanical system as well as eliminate rotation during actuation.

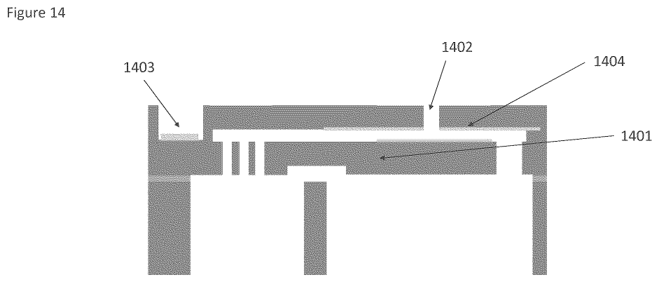

FIG. 14 illustrates the embodiment where a MEMS shutter 202, or its variants 203, 416, 1200 and 1300 can be bonded, soldered, attached to with another silicon device or other suitable layer which has an optical aperture 1402 that has its detail described in FIG. 11. In the embodiment, the optical aperture is a slit or other optical aperture known to a person skilled in the art. The small and precise control of distance between the optical aperture 1402 and the blocker 5 ensures there is no leaking of light when the shutter is in position of the light path. The top device layer can have an opening 1403 to allow for wire bonding access to the bottom device layer. The top device layer can have metal, dielectric coating 1404 at the backside to avoid stiction and block off the light from silicon when infrared light is used.

What is claimed is:

1. A MEMS rotating actuator comprising:
a substrate;
at least one actuator coupled to the substrate by at least a first actuator anchor point and a second actuator anchor point;
a pivoting body;
a first extension arm coupled at a first end thereof to the pivoting body at a first location on the pivoting body, and coupled at a second end thereof to the at least one actuator;
a second extension arm coupled at a first end thereof to the pivoting body at a second location on the pivoting body, and coupled at a second end thereof to a third actuator anchor point; and
an optical element coupled to the pivoting body;
wherein movement of the at least one actuator causes the pivoting body to rotate, thereby moving the optical element.

2. The MEMS rotating actuator of claim 1, wherein the at least one actuator is an electro-thermal actuator.

3. The MEMS rotating actuator of claim 2, wherein the electro-thermal actuator comprises:
at least one beam;
a connecting block coupled centrally on the at least one beam;
the at least one beam coupled at each end thereof to the first actuator anchor point and the second actuator anchor point;
the at least one beam being curved between the first actuator anchor point and the second actuator anchor point, with a highest point of the curve located at the connecting block; and
wherein the at least one beam is thinner adjacent the first actuator anchor point, the second actuator anchor point, and adjacent either side of the connecting block than in a first central area between the connecting block and the first actuator anchor point and a second central area between the connecting block and the second actuator anchor point.

4. The MEMS rotating actuator of claim 1, wherein the optical element is coupled to the pivoting body by an optical element lever to facilitate positioning of the optical element.

5. The MEMS rotating actuator of claim 1, wherein the at least one actuator is an electro-static actuator.

6. The MEMS rotating actuator of claim 2, wherein the at least one actuator comprises a first actuator coupled to the second end of the first extension arm and a second actuator coupled to the second end of the second extension arm; and
wherein the second actuator is coupled to the substrate at a first end of the second actuator by the third actuator anchor point and at a second end of the second actuator by a fourth actuator anchor point.

7. The MEMS rotating actuator of claim 6, wherein the first extension arm and the second extension arm are positioned on opposite sides of the pivoting body.

8. The MEMS rotating actuator of claim 7, wherein the optical element is one of a shutter, blocker, variable attenuator, prism, lens, or polarizer.

9. The MEMS rotating actuator of claim 8, wherein the first extension arm and the second extension arm are parallel to each other.

10. The MEMS rotating actuator of claim 8, wherein the first extension arm is coupled to the pivoting body at a first anchor point and the second extension arm is coupled to the pivoting body at a second anchor point; and wherein the first anchor point and the second anchor point are opposite each other on the pivoting body.

11. The MEMS rotating actuator of claim 6, further comprising:
a third extension arm coupled at a first end thereof to the pivoting body at a third location on the pivoting body; and
wherein the at least one actuator further comprises a third actuator coupled to the substrate via a fifth actuator anchor point and a sixth actuator anchor point; and the second end of the third extension arm is coupled to the third actuator.

12. The MEMS rotating actuator of claim 1, wherein the optical element is one of a shutter, blocker, variable attenuator, prism, lens, or polarizer.

13. The MEMS rotating actuator of claim 6, wherein the optical element is a shutter.

14. A MEMS shutter comprising:
a substrate;
a pivoting body;
an electro-thermal actuator comprising a first actuator and a second actuator, the first actuator coupled to the substrate by at least a first actuator anchor point and a second actuator anchor point, and the second actuator coupled to the substrate at a first end of the second actuator by a third actuator anchor point and at a second end of the second actuator by a fourth actuator anchor point;
a first extension arm coupled at a first end thereof to the pivoting body at a first anchor point on the pivoting body, and coupled at a second end thereof to the first actuator;
a second extension arm coupled at a first end thereof to the pivoting body at a second anchor point on the pivoting body, and coupled at a second end thereof to the second actuator;
the first extension arm and the second extension arm positioned on opposite sides of the pivoting body, the first anchor point and the second anchor point being opposite each other on the pivoting body;
an optical element coupled to the pivoting body, the optical element being one of a shutter, a blocker, a variable attenuator, a prism, a lens, or a polarizer;
wherein movement of the first actuator and the second actuator causes the pivoting body to rotate, thereby moving the optical element; and
a top layer having an optical aperture positioned relative to the shutter such that when the shutter is in a closed position, it is located between the optical element and the substrate, and when the shutter is in an open position the shutter is clear of the optical aperture.

15. A MEMS shutter comprising:
a substrate;
a pivoting body;
an electro-thermal actuator comprising a first actuator and a second actuator, the first actuator coupled to the substrate by at least a first actuator anchor point and a second actuator anchor point, and the second actuator coupled to the substrate at a first end of the second actuator by a third actuator anchor point and at a second end of the second actuator by a fourth actuator anchor point;
a first extension arm coupled at a first end thereof to the pivoting body at a first anchor point on the pivoting body, and coupled at a second end thereof to the first actuator;
a second extension arm coupled at a first end thereof to the pivoting body at a second anchor point on the pivoting body, and coupled at a second end thereof to the second actuator;
the first extension arm and the second extension arm positioned on opposite sides of the pivoting body, the first anchor point and the second anchor point being opposite each other on the pivoting body;
a shutter coupled to the pivoting body;
wherein movement of the first actuator and the second actuator causes the pivoting body to rotate, thereby moving the shutter; and
a top layer having an optical aperture positioned relative to the shutter such that when the shutter is in a closed position, the shutter is located between the optical aperture and the substrate, and when the shutter is in an open position, the shutter is clear of the optical aperture;
wherein the optical aperture is one of a slit, port, group of ports, pin hole, fiber connecting port, or fiducial.
